(19) United States
(12) Patent Application Publication
(10) Pub. No.: US 2025/0240017 A1
(43) Pub. Date: Jul. 24, 2025

(54) SIGNAL TRANSMITTING APPARATUS

(71) Applicant: ROHM CO., LTD., Kyoto-shi (JP)

(72) Inventors: Shinya MASUDA, Kyoto-shi (JP); Masaki ITASAKA, Kyoto-shi (JP)

(21) Appl. No.: 19/073,761

(22) Filed: Mar. 7, 2025

Related U.S. Application Data
(63) Continuation of application No. PCT/JP2023/023589, filed on Jun. 26, 2023.

(30) Foreign Application Priority Data
Sep. 8, 2022 (JP) 2022-143092

(51) Int. Cl. H03K 17/687

(52) U.S. Cl. CPC H03K 17/687

(57) ABSTRACT

An output terminal is connected to the application end of a power supply voltage via a pull-up resistor and a backcurrent prevention diode. An output transistor is provided between the output terminal and a ground. A capacitor is connected between the gate of the output transistor and the output terminal. A charge-discharge circuit charges and discharges the gate of the output transistor during a first level period and during a second level period of a control input signal to turn on and off the output transistor and thereby generates an output signal corresponding to an input signal at the output terminal. A signal generation circuit causes a change in the level of the control input signal when the level of an original input signal is changed. Here, a range in which the control input signal has a second level is adjusted according to the power supply voltage.

### CROSS REFERENCE TO RELATED APPLICATIONS

This application is a continuation under 35 U.S.C. § 120 of International Patent Application No. PCT/JP2023/023589 filed on Jun. 26, 2023, which is incorporated herein by reference, and which claimed priority to Japanese Patent Application No. 2022-143092 filed on Sep. 8, 2022. The present application likewise claims priority under 35 U.S.C. § 119 to Japanese Patent Application No. 2022-143092 filed on Sep. 8, 2022, the entire content of which is also incorporated herein by reference.

### TECHNICAL FIELD

The present disclosure relates to a signal transmitting apparatus.

### BACKGROUND ART

A signal transmitting apparatus is provided which transmits an output signal based on an input signal from an output terminal.

### RELATED ART DOCUMENT

### Patent Document

Patent Document 1: Japanese Unexamined Patent Application Publication No. 2017-200103

### BRIEF DESCRIPTION OF DRAWINGS

FIG. 1 is an overall configuration diagram of a communication system in an embodiment of the present disclosure;

FIG. 2 is an external perspective view showing a transceiver in the embodiment of the present disclosure;

FIG. 3 is a configuration diagram of a transmission circuit in the transceiver in the embodiment of the present disclosure;

FIG. 4 is a diagram showing a configuration for generating a control input signal from an original input signal in the embodiment of the present disclosure;

FIG. 5 is a diagram showing a configuration for generating the original input signal in the embodiment of the present disclosure;

FIG. 6 is a diagram showing a basic relationship between the original input signal and the control input signal in the embodiment of the present disclosure;

FIG. 7 is a diagram for illustrating a signal output condition in the embodiment of the present disclosure;

FIG. 8 is a relationship diagram between a power supply voltage and a charge current or a discharge current in the embodiment of the present disclosure;

FIG. 9 is a diagram schematically showing waveforms of the control input signal and an output voltage in the embodiment of the present disclosure;

FIG. 10 is a diagram schematically showing waveforms of the control input signal and the output voltage when the power supply voltage is relatively high;

FIG. 11 is a diagram schematically showing waveforms of the control input signal and the output voltage when the power supply voltage is relatively low;

FIG. 12 is a diagram showing a state where the low level range of the output voltage depends on the power supply voltage in a reference method;

FIG. 13 is a diagram showing a state where a relationship between the original input signal and the control input signal depends on the power supply voltage in the improvement method of the embodiment of the present disclosure;

FIG. 14 is a diagram showing an example of a relationship between the power supply voltage and a delay time in the improvement method of the embodiment of the present disclosure;

FIG. 15 is a waveform diagram of some signals and voltages in the improvement method of the embodiment of the present disclosure; and

FIG. 16 is a diagram showing another example of the relationship between the power supply voltage and the delay time in the improvement method of the embodiment of the present disclosure.

### DESCRIPTION OF EMBODIMENTS

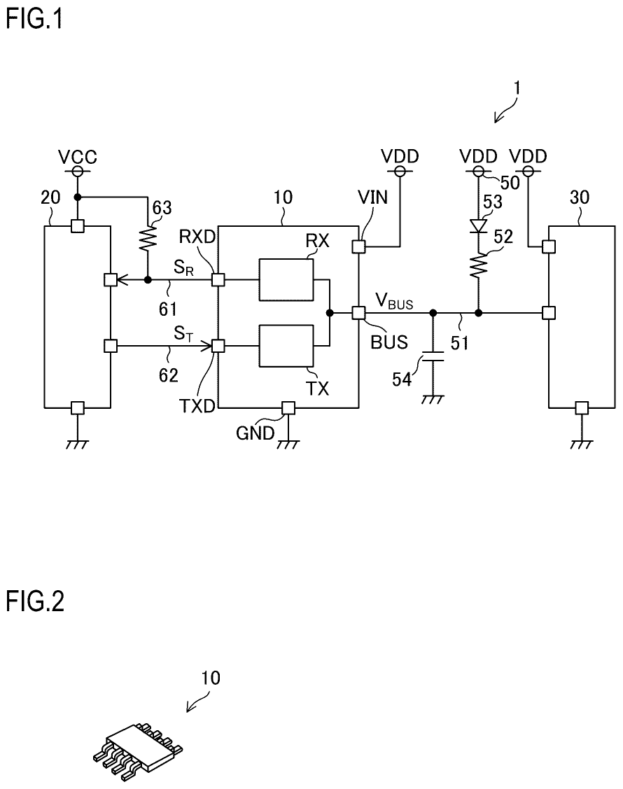

An embodiment of the present disclosure will be specifically described below with reference to drawings. In the referenced drawings, the same parts are identified with the same reference symbols, and the repeated description of the same parts is omitted in principle. In the present specification, for simplification of description, a sign or a symbol indicating information, a signal, a physical quantity, a functional unit, a circuit, an element, a part or the like is written, and thus the name of the information, the signal, the physical quantity, the functional unit, the circuit, the element, the part or the like corresponding to the sign or the symbol may be omitted or written in short. For example, although a bus connection terminal BUS which will be described later and is represented by “BUS” (see FIG. 1) may be written as a bus connection terminal BUS or may be written in short as a terminal BUS, all of them represent the same thing.

A description will first be given of some terms used in the description of the embodiment of the present disclosure. Lines refer to wiring through which electrical signals are propagated or applied. A ground refers to a reference conductive portion having a potential of 0 V (zero volt) as a reference or refers to a potential of 0 V itself. The reference conductive portion may be formed of a conductor such as metal. A potential of 0 V may also be referred to as a ground potential. In the embodiment of the present disclosure, a voltage shown without provision of a specific reference indicates a potential relative to the ground.

A level refers to the level of a potential, and a high level has a higher potential than a low level for any signal or voltage of interest. For any signal or voltage of interest, that the signal or voltage is at a high level strictly means that the level of the signal or voltage is at a high level, and that the signal or voltage is at a low level strictly means that the level of the signal or voltage is at a low level. The level of a signal may be referred to as a signal level, and the level of a voltage may be referred to as a voltage level.

In any signal or voltage of interest, a switch from a low level to a high level is referred to as an up edge. A timing at which the up edge occurs is referred to as an up edge timing. The up edge may be replaced by a rising edge. In any signal or voltage of interest, a switch from a high level to a low level is referred to as a down edge. A timing at which the down edge occurs is referred to as a down edge timing. The down edge may be replaced by a falling edge.

For any transistor configured as an FET (field-effect transistor) including a MOSFET, an on state refers to a state where the drain and the source of the transistor are conductive, and an off state refers to a state (blocked state) where the drain and the source of the transistor are nonconductive. The same is true for transistors which are not classified as FETs. Unless otherwise specified, the MOSFET is understood to be an enhancement type MOSFET. The MOSFET is an abbreviation for “metal-oxide-semiconductor field-effect transistor”. Unless otherwise specified, in any MOSFET, a back gate may be considered to be shorted to the source.

For any signal which has a high or low signal level, a period during which the signal level is high is referred to as a high level period, and a period during which the signal level is low is referred to as a low level period. The same is true for any voltage which has a high or low voltage level.

Unless otherwise specified, connection between a plurality of parts, such as a circuit element, wiring (line), and a node, which form a circuit is understood to refer to electrical connection.

FIG. 1 shows an overall configuration diagram of a communication system 1 in the embodiment of the present disclosure. The communication system 1 includes a transceiver 10, a microcomputer 20 and a other side device 30. A bus line 51, a pull-up resistor 52, a backcurrent prevention diode 53, a capacitor 54, a data line 61, a data line 62 and a pull-up resistor 63 are also included in the constituent elements of the communication system 1.

FIG. 2 is an external perspective view of the transceiver 10. The transceiver 10 is an electronic component which includes: a semiconductor chip that includes a semiconductor integrated circuit formed on a semiconductor substrate; a housing (package) that stores the semiconductor chip; and a plurality of external terminals that are exposed from the housing to the outside of the transceiver 10. The semiconductor chip is sealed into the housing (package) formed of resin, and thus the transceiver 10 is formed. The number of external terminals of the transceiver 10 and the type of housing of the transceiver 10 shown in FIG. 2 are merely examples and can be designed arbitrarily. FIG. 1 shows a power supply terminal VIN, a bus connection terminal BUS, a ground terminal GND, a reception data output terminal RXD and a transmission data input terminal TXD which are included in the external terminals. External terminals other than these terminals (such as a sleeve control input terminal) can also be provided in the transceiver 10.

A power supply voltage VDD is supplied from an unillustrated voltage source to the power supply terminal VIN. The power supply voltage VDD has a predetermined positive direct-current voltage value. The transceiver 10 is driven based on the power supply voltage VDD. The ground terminal GND is connected to the ground. The bus connection terminal BUS is connected to one end of the bus line 51, and the other end of the bus line 51 is connected to the other side device 30. In other words, the bus connection terminal BUS is connected to the other side device 30 via the bus line 51. The other side device 30 also includes a terminal which receives the power supply voltage VDD and a terminal which is connected to the ground and is driven based on the power supply voltage VDD.

The bus line 51 is connected to the application end 50 of the power supply voltage VDD via the pull-up resistor 52 and the backcurrent prevention diode 53. The application end 50 is a terminal to which the power supply voltage VDD is applied. The backcurrent prevention diode 53 has a forward direction from the application end 50 toward the bus line 51 and the bus connection terminal BUS. The backcurrent prevention diode 53 blocks the flow of current from the bus line 51 to the application end 50. More specifically, the anode of the backcurrent prevention diode 53 is connected to the application end 50, the cathode of the backcurrent prevention diode 53 is connected to one end of the pull-up resistor 52 and the other end of the pull-up resistor 52 is connected to the bus line 51.

However, the positions of the pull-up resistor 52 and the backcurrent prevention diode 53 can be reversed from those shown in FIG. 1. Specifically, the application end 50 may be connected to the anode of the backcurrent prevention diode 53 via the pull-up resistor 52, and the cathode of the backcurrent prevention diode 53 may be connected to the bus line 51.

The capacitor 54 is connected between the bus line 51 and the ground. In other words, one end of the capacitor 54 is connected to the bus line 51, and the other end of the capacitor 54 is connected to the ground. The capacitor 54 may be formed with a plurality of capacitors separated from each other. The capacitor 54 may be omitted.

The reception data output terminal RXD is connected to one end of the data line 61, and the other end of the data line 61 is connected to the microcomputer 20. The transmission data input terminal TXD is connected to one end of the data line 62, and the other end of the data line 62 is connected to the microcomputer 20. In other words, the terminals RXD and TXD are connected to the microcomputer 20 via the data lines 61 and 62. The data line 61 is connected to the application end of a power supply voltage VCC via the pull-up resistor 63. The power supply voltage VCC has a predetermined positive direct-current voltage value. It does not matter whether the power supply voltages VCC and VDD match. The microcomputer 20 includes a terminal which receives the power supply voltage VCC and a terminal which is connected to the ground and is driven based on the power supply voltage VCC.

The transceiver 10 includes a reception circuit RX and a transmission circuit TX. The reception circuit RX is connected to the reception data output terminal RXD and the bus connection terminal BUS. The transmission circuit TX is connected to the transmission data input terminal TXD and the bus connection terminal BUS.

The transceiver 10 and the other side device 30 perform bidirectional communication with a half-duplex system via the bus line 51. The bidirectional communication which is assumed in the present embodiment is serial communication (that is, serial communication using the bus line 51 which is one wire) using a single wire system. In the bidirectional communication of the half-duplex system, the transceiver 10 may function as a master, and the other side device 30 may function as a slave, or the other side device 30 may function as a master, and the transceiver 10 may function as a slave. The bidirectional communication between the transceiver 10 and the other side device 30 may be, for example, bidirectional communication which conforms to a LIN (Local Interconnect Network) standard or a CXPI (Clock Extension Peripheral Interface) standard.

In the bidirectional communication of the half-duplex system, one of the transceiver 10 and the other side device 30 is operated as a transmission-side device, and the other is operated as a reception-side device.

When the transceiver 10 functions as the reception-side device, the other side device 30 transmits a signal (hereinafter referred to as the signal S_{R}) via the bus line 51, and the reception circuit RX receives, at the bus connection terminal BUS, the signal S_{R} transmitted from the other side device 30. The reception circuit RX transmits the received signal S_{R} from the terminal RXD via the data line 61 to the microcomputer 20. When the transceiver 10 functions as the reception-side device, the bus connection terminal BUS functions as an input terminal (signal reception terminal) which receives a signal transmitted from the other side device 30.

When the transceiver 10 functions as the transmission-side device, the microcomputer 20 transmits a signal (hereinafter referred to as the signal S_{T}) to the transceiver 10 via the data line 62. The signal S_{T} transmitted from the microcomputer 20 is received by the terminal TXD. When the transceiver 10 functions as the transmission-side device, the transmission circuit TX transmits the signal S_{T} received from the microcomputer 20 to the other side device 30 via the bus line 51. The other side device 30 may be formed with a group of a transceiver and a microcomputer equivalent to the transceiver 10 and the microcomputer 20, and in this case, the signal S_{T} received from the transceiver 10 is transmitted from the transceiver in the other side device 30 to the microcomputer in the other side device 30. When the transceiver 10 functions as the transmission-side device, the bus connection terminal BUS functions as an output terminal (signal transmission terminal) at which the signal to be transmitted from the transceiver 10 appears.

The transmission of a signal via the bus line 51 is realized by controlling the level of the bus line 51 such that the level of the bus line 51 is high or low. The level of the bus line 51 is the same as the level of the bus connection terminal BUS. The level of the bus line 51 is equal to or greater than 0 V and equal or less than the power supply voltage VDD. When the bus line 51 has a level which is equal to or greater than a voltage (VDD×k_{H}), the level of the bus line 51 is high, and when the bus line 51 has a level which is equal to or less than a voltage (VDD×k_{L}), the level of the bus line 51 is low. Here, “1>k_{H}>0.5>k_{L}>0” holds true, and for example, (k_{H}, k_{L})=(0.7, 0.3). The voltages of the bus line 51 and the bus connection terminal BUS are represented by a symbol “V_{BUS}”.

Unless otherwise specified, the operation and the configuration when the transceiver 10 functions as the transmission-side device will be described below. For the transmission circuit TX, the voltage V_{BUS} corresponds to an output voltage (the output voltage of the transmission circuit TX). Hence, the voltage V_{BUS} when attention is focused on the configuration and the operation of the transmission circuit TX can be referred to as the output voltage in the following description. A signal indicated by the output voltage V_{BUS} can be referred to as the output signal. When the level of the bus line 51 is caused to transition between a high level and a low level in the transmission of a signal via the bus line 51, the transmission circuit TX in the transceiver 10 has the function of controlling the slew rate of the output voltage V_{BUS} to reduce radiation noise.

### [Basic Configuration of Transmission Circuit TX]

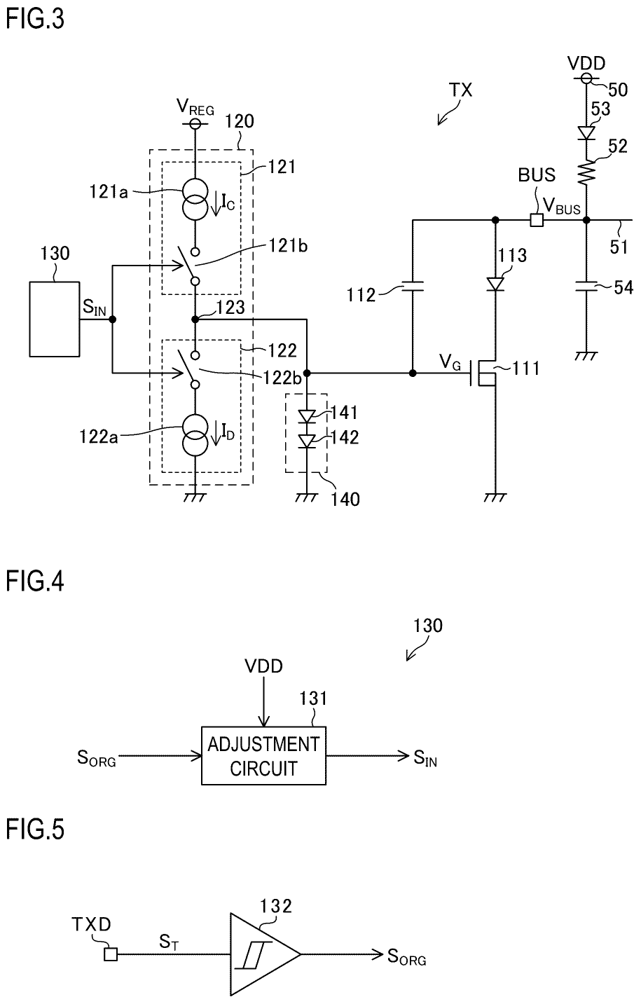

FIG. 3 shows the basic configuration of the transmission circuit TX. The transmission circuit TX of the basic configuration includes an output transistor 111, a capacitor (feedback capacitor) 112, a backcurrent prevention diode 113, a charge-discharge circuit 120, a control input signal supply circuit 130 and a gate voltage restriction circuit 140.

The output transistor 111 is an N-channel MOSFET. The output transistor 111 is provided between the bus connection terminal BUS which functions as the output terminal and the ground, and the transmission circuit TX uses the output transistor 111 of an open drain configuration to transmit a signal. However, the backcurrent prevention diode 113 for blocking the flow of current from the ground to the bus line 51 via the output transistor 111 and the bus connection terminal BUS is provided between the output transistor 111 and the bus connection terminal BUS. Specifically, the drain of the output transistor 111 is connected to the cathode of the backcurrent prevention diode 113, and the anode of the backcurrent prevention diode 113 is connected to the bus connection terminal BUS. The source of the output transistor 111 is connected to the ground. The gate voltage of the output transistor 111 (that is, the voltage applied to the gate of the output transistor 111) is represented by a symbol “V_{G}”. The gate threshold voltage of the output transistor 111 is represented by a symbol “V_{G_TH}”. The gate threshold voltage V_{G_TH} has a positive voltage value which depends on the characteristic of the output transistor 111. When the gate voltage V_{G} of the output transistor 111 is less than the gate threshold voltage V_{G_TH}, the output transistor 111 is in an off state, and when the gate voltage V_{G} of the output transistor 111 is equal to or greater than the gate threshold voltage V_{G_TH}, the output transistor 111 is in an on state.

A variation in which the backcurrent prevention diode 113 is not provided in the transmission circuit TX can be adopted, and when the variation is adopted, the drain of the output transistor 111 is directly connected to the bus connection terminal BUS.

The capacitor 112 is connected between the gate of the output transistor 111 and the bus connection terminal BUS. Specifically, one end of the capacitor 112 is connected to the gate of the output transistor 111, and the other end of the capacitor 112 is connected to the bus connection terminal BUS.

The charge-discharge circuit 120 charges or discharges the gate of the output transistor 111 according to a control input signal S_{IN}. The charge-discharge circuit 120 charges the gate of the output transistor 111 to be able to control the output transistor 111 such that the output transistor 111 is in an on state and discharges the gate of the output transistor 111 to be able to control the output transistor 111 such that the output transistor 111 is in an off state. The control input signal S_{IN} is a binary signal which has a high level or a low level. The control input signal S_{IN} of a high level substantially has the potential of an internal power supply voltage V_{REG}, and the control input signal S_{IN} of a low level substantially has a ground potential. By a regulator (not shown) in the transceiver 10, the internal power supply voltage V_{REG} which is a positive direct-current voltage is generated from the power supply voltage VDD. The charge-discharge circuit 120 includes a charging circuit 121 and a discharging circuit 122.

The charging circuit 121 supplies a charge current to the gate of the output transistor 111 during a period in which the control input signal S_{IN} is high to increase the gate voltage V_{G} of the output transistor 111. However, the gate voltage V_{G} has an upper limit, and thus the gate voltage V_{G} is prevented from being increased beyond an upper limit voltage. The upper limit voltage of the gate voltage V_{G} is the internal power supply voltage V_{REG} or a predetermined voltage which is lower than the internal power supply voltage V_{REG}. The upper limit voltage of the gate voltage V_{G} is higher than the gate threshold voltage V_{G_TH} of the output transistor 111. In a process in which the gate voltage V_{G} is increased from a sufficiently low voltage (for example, 0 V), when the gate voltage V_{G} reaches the gate threshold voltage V_{G_TH}, the output transistor 111 is switched from an off state to an on state. Specifically, in the process in which the gate voltage V_{G} is increased from the sufficiently low voltage (for example, 0 V), when the gate voltage V_{G} becomes equal to or greater than the gate threshold voltage V_{G_TH}, the resistance value of the channel of the output transistor 111 is sharply decreased, and thus the resistance value of the channel of the output transistor 111 is sufficiently lower than the resistance value of the pull-up resistor 52, with the result that the voltage V_{BUS} is substantially decreased to 0 V. The resistance value of the channel of the output transistor 111 refers to a resistance value between the drain and the source of the output transistor 111.

The discharging circuit 122 draws a discharge current from the gate of the output transistor 111 during a period in which the control input signal S_{IN} is low to decrease the gate voltage V_{G} of the output transistor 111. However, the gate voltage V_{G} has a lower limit, and thus the gate voltage V_{G} is prevented from being decreased below a lower limit voltage. The lower limit voltage of the gate voltage V_{G} is 0 V. In a process in which the gate voltage V_{G} is decreased from a voltage higher than the gate threshold voltage V_{G_TH}, when the gate voltage V_{G} is decreased below the gate threshold voltage V_{G_TH}, the output transistor 111 is switched from an on state to an off state. Specifically, in the process in which the gate voltage V_{G} is decreased from the voltage higher than the gate threshold voltage V_{G_TH}, when the gate voltage V_{G} becomes less than the gate threshold voltage V_{G_TH}, the resistance value of the channel of the output transistor 111 is sharply increased, and thus the resistance value of the channel of the output transistor 111 is sufficiently increased beyond the resistance value of the pull-up resistor 52, with the result that the output voltage V_{BUS} is increased to around the power supply voltage VDD.

In the configuration example of FIG. 3, the charging circuit 121 is formed with a series circuit of a charge current source 121a and a switch 121b, and the discharging circuit 122 is formed with a series circuit of a discharge current source 122a and a switch 122b. The charge current source 121a is provided between the application end of the internal power supply voltage V_{REG} and the switch 121b to generate a current I_{C} based on the internal power supply voltage V_{REG}. The switch 121b is provided between the charge current source 121a and a node 123. The discharge current source 122a is provided between the ground and the switch 122b to generate a current I_{D} based on the internal power supply voltage V_{REG}. The switch 122b is provided between the discharge current source 122a and the node 123. The node 123 is connected to the gate of the output transistor 111. The switches 121b and 122b are controlled based on the control input signal S_{IN} to be turned on or off.

During the period in which the control input signal S_{IN} is high, the switch 121b is on whereas the switch 122b is off. Hence, during the period in which the control input signal S_{IN} is high, the current I_{C} (hereinafter referred to as the charge current I_{C}) for increasing the gate voltage V_{G} is supplied from the charge current source 121a to the gate of the output transistor 111 via the switch 121b and the node 123. During the period in which the control input signal S_{IN} is low, the exchange of charge between the gate of the output transistor 111 and the charging circuit 121 is not performed.

During the period in which the control input signal S_{IN} is low, the switch 121b is off whereas the switch 122b is on. Hence, during the period in which the control input signal S_{IN} is low, the current I_{D} (hereinafter referred to as the discharge current I_{D}) for lowing the gate voltage V_{G} is drawn from the gate of the output transistor 111 to the discharge current source 122a via the node 123 and the switch 122b. During the period in which the control input signal S_{IN} is high, the exchange of charge between the gate of the output transistor 111 and the discharging circuit 122 is not performed.

The control input signal supply circuit 130 generates the control input signal S_{IN} based on the signal S_{T} received from the microcomputer 20 and supplies the control input signal S_{IN} to the charge-discharge circuit 120. The control input signal supply circuit 130 generates the control input signal S_{IN} through waveform shaping of the signal S_{T} or the like.

As long as the charge current I_{C} can be supplied to the gate of the output transistor 111 during the period in which the control input signal S_{IN} is high, the configuration of the charging circuit 121 is not limited. During the period in which the control input signal S_{IN} is low, the charging circuit 121 may stop the generation of the charge current I_{C}. In any case, during the period in which the control input signal S_{IN} is low, the charge current I_{C} flowing from the charging circuit 121 to the gate of the output transistor 111 is zero. Likewise, as long as the discharge current I_{D} can be drawn from the gate of the output transistor 111 during the period in which the control input signal S_{IN} is low, the configuration of the discharging circuit 122 is not limited. During the period in which the control input signal S_{IN} is high, the discharging circuit 122 may stop the generation of the discharge current I_{D}. In any case, during the period in which the control input signal S_{IN} is high, the discharge current I_{D} flowing from the gate of the output transistor 111 to the discharging circuit 122 is zero.

The gate voltage restriction circuit 140 is connected to the gate of the output transistor 111 and the ground. The gate voltage restriction circuit 140 includes two diodes 141 and 142. The anode of the diode 141 is connected to the gate of the output transistor 111, the cathode of the diode 141 is connected to the anode of the diode 142 and the cathode of the diode 142 is connected to the ground. The gate voltage restriction circuit 140 has the function of suppressing an event in which the gate voltage V_{G} is equal to or greater than a predetermined restriction voltage V_{LIM}, and as long as the gate voltage restriction circuit 140 has the function, the gate voltage restriction circuit 140 is not limited. The restriction voltage V_{LIM} here is higher than the gate threshold voltage V_{G_TH}, and in the configuration example of FIG. 3, the restriction voltage V_{LIM} corresponds to the sum of the forward voltages of the diodes 141 and 142. The circuit 140 may be formed with a series circuit of three or more diodes.

In a process in which the gate voltage V_{G} is increased based on the charge current I_{C} to switch the output transistor 111 from an off state to an on state, the output voltage V_{BUS} is decreased, and the decrease in the output voltage V_{BUS} is fed back to the gate of the output transistor 111 via the capacitor 112. By contrast, in a process in which the gate voltage V_{G} is decreased based on the discharge current I_{D} to switch the output transistor 111 from an on state to an off state, the output voltage V_{BUS} is increased, and the increase in the output voltage V_{BUS} is fed back to the gate of the output transistor 111 via the capacitor 112. Hence, for the charge-discharge circuit 120, the capacitance value of the capacitor 112 appears equivalently larger than the actual capacitance value of the capacitor 112 due to the mirror effect. In other words, the capacitor 112 functions as a mirror capacitance.

### [Control Input Signal Supply Circuit]

As shown in FIG. 4, the control input signal supply circuit 130 includes an adjustment circuit 131 (signal generation circuit). An original input signal S_{ORG} is input to the adjustment circuit 131. As with the control input signal S_{IN}, the original input signal S_{ORG} is a binary signal which has a high level or a low level. The original input signal S_{ORG} is a signal based on the signal S_{T} received from the microcomputer 20. With reference to FIG. 5, for example, a Schmitt trigger buffer 132 connected to the terminal TXD is provided in the control input signal supply circuit 130, and the Schmitt trigger buffer 132 binarizes the potential of the signal S_{T} to generate the original input signal S_{ORG}. The signal S_{T} itself may be the original input signal S_{ORG}.

The adjustment circuit 131 generates and outputs the control input signal S_{IN} based on the original input signal S_{ORG}. Here, the adjustment circuit 131 adjusts the low level range of the control input signal S_{IN} according to the power supply voltage VDD. In any signal or voltage of interest, the length of the low level period and the length of the high level period of the signal or voltage of interest are referred to as the low level range and the high level range, respectively. Hence, for example, the low level range of the control input signal S_{IN} indicates the length of the low level period of the control input signal S_{IN}, and the high level range of the output voltage V_{BUS} indicates the length of the high level period of the output voltage V_{BUS}.

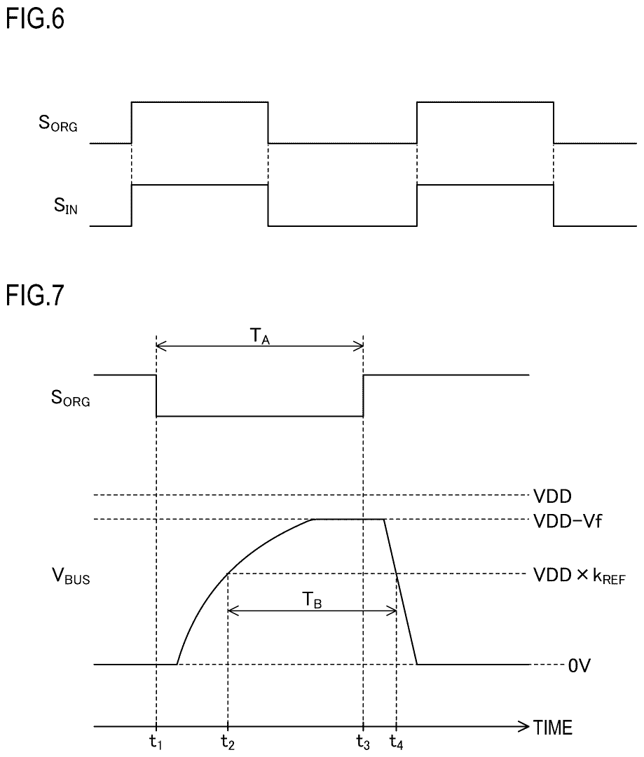

As shown in FIG. 6, in principle, the adjustment circuit 131 causes the control input signal S_{IN} to have a high level during a period in which the original input signal S_{ORG} is high, and causes the control input signal S_{IN} to have a low level during a period in which the original input signal S_{ORG} is low. However, depending on the power supply voltage VDD, the adjustment circuit 131 adjusts the low level range of the control input signal S_{IN} based on the low level range of the original input signal S_{ORG} to cause the low level range of the control input signal S_{IN} to differ from the low level range of the original input signal S_{ORG}. This will be described in detail later.

### [Output Signal Condition]

The slew rate of the output voltage V_{BUS} includes an up slew rate which is a slew rate when the output voltage V_{BUS} is increased, and a down slew rate which is a slew rate when the output voltage V_{BUS} is decreased. The up slew rate refers to the maximum value or the average value of the rate of change of the output voltage V_{BUS} when the output voltage V_{BUS} is increased. The down slew rate refers to the maximum value or the average value of the rate of change of the output voltage V_{BUS} when the output voltage V_{BUS} is decreased. In the following description, the up slew rate and the down slew rate are collectively referred to as the output slew rate. In the following description, the output slew rate is understood to refer to one of the up slew rate and the down slew rate or to refer to both the up slew rate and the down slew rate.

Although a decrease in the output slew rate contributes to a reduction in radiation noise, the transceiver 10 which is operated as the transmission-side device needs to satisfy the following output signal condition. The output signal condition here may be, for example, a condition which is defined in the LIN standard or the CXPI standard.

The output signal condition which needs to be satisfied by the transceiver 10 will be described with reference to FIG. 7. FIG. 7 shows the waveforms of the original input signal S_{ORG} and the output voltage V_{BUS}. The length of the low level period of the original input signal S_{ORG} is represented by a time T_{A} (a time period T_{A}). Although the low level period and the high level period of the original input signal S_{ORG} appear alternately and repeatedly, the length of a certain low level period of interest among the low level periods of the original input signal S_{ORG} is represented by the time T_{A}. Specifically, it is assumed that a down edge occurs in the original input signal S_{ORG} at a time point t₁, and thereafter, an up edge occurs in the original input signal S_{ORG} at a time point t₃. In this case, a time from the time point t₁ to the time point t₃ is the time T_{A}. A time point t₂ shown in FIG. 7 is after the time point t₁ and before the time point t₃. A time point t₄ is after the time point t₃.

When the down edge occurs in the original input signal S_{ORG} at the time point t₁, a down edge also occurs in the control input signal S_{IN}, and thus the discharge current I_{D} starts to be drawn from the gate of the output transistor 111. When the gate voltage V_{G} is decreased to the gate threshold voltage V_{G_TH} by the discharge current I_{D}, based on an increase in the resistance value of the channel of the output transistor 111, the output voltage V_{BUS} starts to be increased from 0 V or a voltage close to 0 V. Thereafter, at the time point t₂, the output voltage V_{BUS} reaches a voltage (VDD×k_{REF}). The voltage (VDD×k_{REF}) is the k_{REF} times the power supply voltage VDD. Here, k_{REF} has a positive predetermined value which is determined by a standard (for example, the LIN standard or the CXPI standard) applied to the communication system 1 and is less than 1, and k_{REF} may be the same as the coefficient k_{H} described previously. Here, it is assumed that “k_{REF}=k_{H}=0.7”. The output voltage V_{BUS} is increased after the time point t₂.

Then, at the time point t₃, the up edge occurs in the original input signal S_{ORG}. When the up edge occurs in the original input signal S_{ORG} at the time point t₃, an up edge also occurs in the control input signal S_{IN}, and thus the discharging of the gate of the output transistor 111 is stopped, and instead, the gate of the output transistor 111 starts to be charged. When the gate voltage V_{G} is increased to the gate threshold voltage V_{G_TH} by the charge current I_{C}, based on a decrease in the resistance value of the channel of the output transistor 111, the output voltage V_{BUS} starts to be decreased from a voltage exceeding the voltage (VDD×k_{REF}). Thereafter, at the time point t₄, the output voltage V_{BUS} is decreased to the voltage (VDD×k_{REF}). The output voltage V_{BUS} is decreased after the time point t₄.

A length between the time point t₂ and the time point t₄ is represented by a time T_{B} (a time period T_{B}). The time T_{B} corresponds to the high level range of the output voltage V_{BUS}. The output signal condition is that the ratio of the time T_{B} to the time T_{A}, that is, the ratio (T_{B}/T_{A}) is equal to or greater than a predetermined threshold value R_{TH}. When “T_{B}/T_{A}≥R_{TH}”, the output signal condition is satisfied, and when “T_{B}/T_{A}<R_{TH}”, the output signal condition is not satisfied. The threshold value R_{TH} has a positive predetermined value which is determined by a standard (for example, the LIN standard or the CXPI standard) applied to the communication system 1 and is less than 1, and for example, “R_{TH}=0.8”.

The forward voltage of the backcurrent prevention diode 53 is represented by a symbol “Vf”. During the period in which the original input signal S_{ORG} is low, the output voltage V_{BUS} is not increased beyond a voltage (VDD−Vf).

On the other hand, in the communication system 1, the power supply voltage VDD has a voltage within a power supply voltage range from a minimum voltage VDD_{MIN} to a maximum voltage VDD_{MAX}. The minimum voltage VDD_{MIN} and the maximum voltage VDD_{MAX} have a positive predetermined voltage value which satisfies “0<VDD_{MIN}<VDD_{MAX}”. As long as the power supply voltage VDD is within the power supply voltage range, it is required that the output signal condition is constantly satisfied. If the output slew rate is constantly set large enough, the output signal condition is easily satisfied, but an increase in the output slew rate causes an increase in radiation noise.

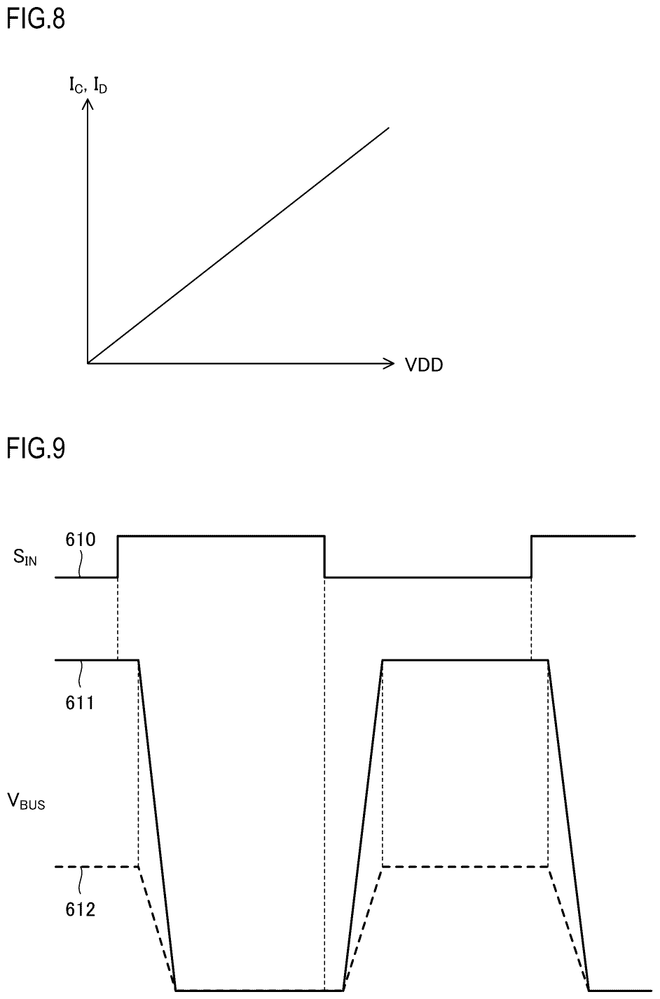

Hence, in order to satisfy the output signal condition in the entire power supply voltage range while minimizing radiation noise, in the transceiver 10, the output slew rate is set according to the power supply voltage VDD. The up slew rate depends on the charge current I_{C}, and the down slew rate depends on the discharge current I_{D}. Hence, the charge-discharge circuit 120 sets, according to the power supply voltage VDD, the values of the charge current I_{C} and the discharge current I_{D} such that they are variable, and thereby sets, according to the power supply voltage VDD, the output slew rate such that the output slew rate is variable. Specifically, the charging circuit 121 increases the charge current I_{C} as the power supply voltage VDD is increased, and the discharging circuit 122 increases the discharge current I_{D} as the power supply voltage VDD is increased. Typically, for example, as shown in FIG. 8, the charging circuit 121 may cause the charge current I_{C} to be proportional to the power supply voltage VDD, and the discharging circuit 122 may cause the discharge current I_{D} to be proportional to the power supply voltage VDD.

A relationship between the output voltage V_{BUS} and the power supply voltage VDD will be described with reference to FIG. 9. FIG. 9 shows examples of waveforms of the original input signal S_{ORG} and the output voltage V_{BUS}. In FIG. 9, a rectangular waveform 610 is an example of the waveform of the original input signal S_{ORG}. In FIG. 9, a solid polygonal line waveform 611 is an example of the waveform of the output voltage V_{BUS} when “VDD=VDD_{MAX}”, and a dashed polygonal line waveform 612 is an example of the waveform of the output voltage V_{BUS} when “VDD=VDD_{MIN}”. The waveforms 611 and 612 partially overlap each other. In the example of FIG. 9, the charge current I_{C} and the discharge current I_{D} are caused to be proportional to the power supply voltage VDD, and thus the output slew rate is caused to be proportional to the power supply voltage VDD.

### [Reference Method]

Here, the effect of the backcurrent prevention diode 53 on an output signal waveform (that is, the waveform of the output voltage V_{BUS}) will be described.

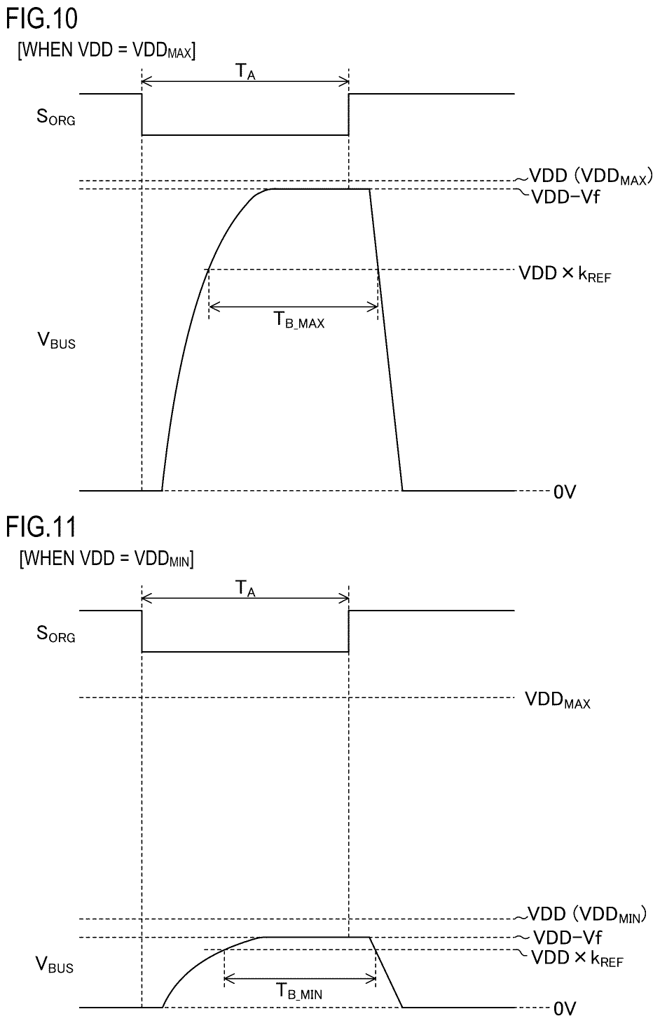

FIG. 10 schematically shows waveforms of the original input signal S_{ORG} and the output voltage V_{BUS} when “VDD=VDD_{MAX}”. The time T_{B} when “VDD=VDD_{MAX}” is particularly referred to as the time T_{B_MAX}. FIG. 11 schematically shows waveforms of the original input signal S_{ORG} and the output voltage V_{BUS} when “VDD=VDD_{MIN}”. The time T_{B} when “VDD=VDD_{MIN}” is particularly referred to as the time T_{B_MIN}.

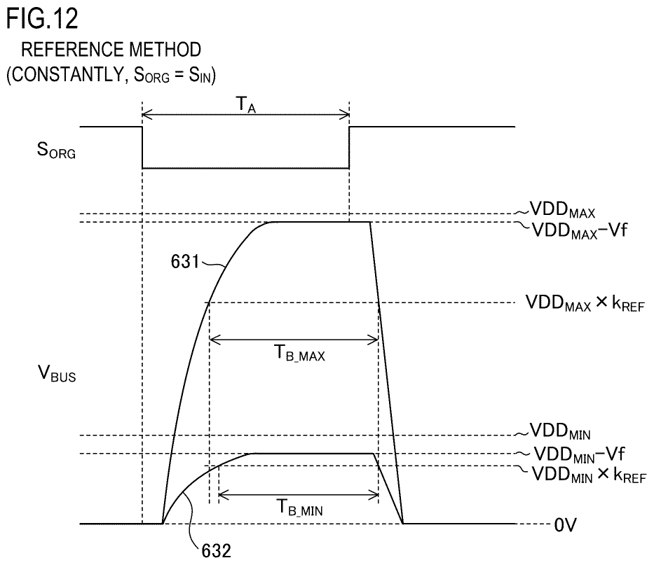

FIG. 12 shows waveforms of the original input signal S_{ORG}, the control input signal S_{IN} and the output voltage V_{BUS} in a reference method. In the reference method, “S_{ORG}=S_{IN}” constantly holds true regardless of the power supply voltage VDD. FIG. 12 corresponds to waveforms obtained by overlapping the waveforms of FIGS. 10 and 11 when it is assumed that “S_{ORG}=S_{IN}” constantly holds true regardless of the power supply voltage VDD. In the reference method, a waveform 631 is a waveform of the output voltage V_{BUS} when “VDD=VDD_{MAX}”. In the reference method, a waveform 632 is a waveform of the output voltage V_{BUS} when “VDD=VDD_{MIN}”. As the power supply voltage VDD is decreased, the ratio of the forward voltage Vf (the forward voltage Vf of the backcurrent prevention diode 53) to the supply voltage VDD is increased. Hence, in the reference method, the time T_{B_MIN} is shorter than the time T_{B_MAX}. In other words, in the reference method, the high level range (T_{B_MIN}) of the output voltage V_{BUS} when “VDD=VDD_{MIN}” is shorter than the high level range (T_{B_MAX}) of the output voltage V_{BUS} when “VDD=VDD_{MAX}”.

A description will be further given using specific numerical examples. As described above, here, it is assumed that “K_{REF}=0.7”. It is further assumed that (VDD_{MAX}, VDD_{MIN}, Vf)=(27 V, 5 V, 0.7 V).

In a case where “VDD=VDD_{MAX}”, “(VDD_{MAX}−Vf)=26.3 V”, “VDD×k_{REF}=VDD_{MAX}×0.7=18.9 V” and “18.9/26.3≈0.719”. Hence, in a case where “VDD=VDD_{MAX}”, in the reference method, the output voltage V_{BUS} needs to be increased from 0 V by about 0.719 times the voltage (VDD−Vf) so that the output voltage V_{BUS} reaches the voltage (VDD×k_{REF}) after down edges occur in the original input signal S_{ORG} and the control input signal S_{IN}. In a case where “VDD=VDD_{MIN}”, “(VDD_{MIN}−Vf)=4.3 V”, “VDD×k_{REF}=VDD_{MIN}×0.7=3.5 V” and “3.5/4.3≈0.814”. Hence, in a case where “VDD=VDD_{MIN}”, in the reference method, the output voltage V_{BUS} needs to be increased from 0 V by about 0.814 times the voltage (VDD−Vf) so that the output voltage V_{BUS} reaches the voltage (VDD×k_{REF}) after down edges occur in the original input signal S_{ORG} and the control input signal S_{IN}.

In the reference method, a time necessary to increase the output voltage V_{BUS} by about 0.814 times the voltage (VDD−Vf) is longer than a time necessary to increase the output voltage V_{BUS} by about 0.719 times the voltage (VDD−Vf). Consequently, in the reference method, “T_{B_MAX}>T_{B_MIN}”. This means that, for example, if it is assumed that the original input signal S_{ORG} is a periodic rectangular wave signal, the H duty of the output voltage V_{BUS} is changed depending on the power supply voltage VDD. When the original input signal S_{ORG} is a periodic rectangular wave signal, the output voltage V_{BUS} is also periodic, and the H duty of the output voltage V_{BUS} indicates the ratio of the high level range of the output voltage V_{BUS} which occupies one period of the output voltage V_{BUS}.

### [Improvement Method]

It is not desirable that the high level range of the output voltage V_{BUS} be changed depending on the power supply voltage VDD. It is often required to suppress the amount of change in the high level range of the output voltage V_{BUS} relative to a change in the power supply voltage VDD to a predetermined amount or less. An improvement method for meeting this requirement is applied to the transceiver 10.

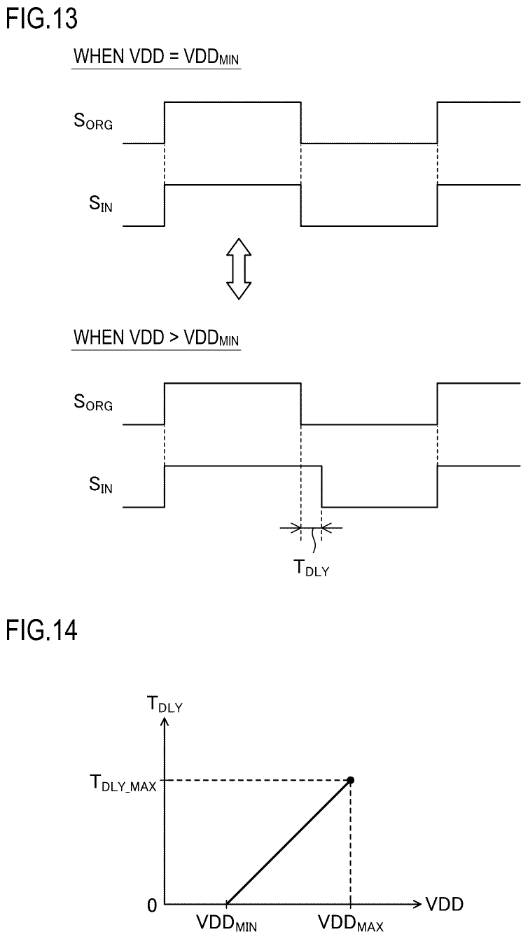

The improvement method will be described with reference to FIGS. 13 and 14. The adjustment circuit 131 shown in FIG. 4 causes a down edge to occur in the control input signal S_{IN} when a down edge occurs in the original input signal S_{ORG}, and causes an up edge to occur in the control input signal S_{IN} when an up edge occurs in the original input signal S_{ORG}. This respect does not depend on the power supply voltage VDD. However, the adjustment circuit 131 adjusts, based on the low level range of the original input signal S_{ORG}, the low level range of the control input signal S_{IN} according to the power supply voltage VDD.

By the adjustment described above, for the power supply voltage VDD, the low level range of the control input signal S_{IN} is caused to differ from the low level range of the original input signal S_{ORG}. This corresponds to causing the duty of the control input signal S_{IN} to differ from the duty of the original input signal S_{ORG} according to the power supply voltage VDD when the original input signal S_{ORG} is a periodic signal.

Specifically, during the period in which the original input signal S_{ORG} is high, the adjustment circuit 131 sets the level of the control input signal S_{IN} to a high level constantly (hence, without depending on the power supply voltage VDD). While the adjustment circuit 131 causes a down edge to occur in the control input signal S_{IN} when a down edge occurs in the original input signal S_{ORG}, that is, during a period after the timing of the down edge of the original input signal S_{ORG} until the timing of the down edge of the control input signal S_{IN}, the adjustment circuit 131 inserts a delay time T_{DLY} according to the power supply voltage VDD. However, the delay time T_{DLY} is not inserted when “VDD=VDD_{MIN}”.

In other words, when “VDD=VDD_{MIN}”, the adjustment circuit 131 causes the high level period of the original input signal S_{ORG} to coincide with the high level period of the control input signal S_{IN}, and causes the low level period of the original input signal S_{ORG} to coincide with the low level period of the control input signal S_{IN}. Hence, in a case where “VDD=VDD_{MIN}”, when the level of the original input signal S_{ORG} transitions from a high level to a low level, the adjustment circuit 131 immediately causes the level of the control input signal S_{IN} to transition from a high level to a low level without providing the delay time T_{DLY}.

On the other hand, in a case where “VDD>VDD_{MIN}”, when the level of the original input signal S_{ORG} transitions from a high level to a low level, the adjustment circuit 131 causes the level of the control input signal S_{IN} to transition from a high level to a low level after the delay time T_{DLY}.

When the level of the original input signal S_{ORG} transitions from a low level to a high level, the adjustment circuit 131 immediately causes the level of the control input signal S_{IN} to transition from a low level to a high level without depending on the power supply voltage VDD.

FIG. 14 shows a relationship between the power supply voltage VDD and the delay time T_{DLY} in the improvement method. The delay time T_{DLY} when “VDD=VDD_{MIN}” is zero. When “VDD>VDD_{MIN}”, the adjustment circuit 131 increases the delay time T_{DLY} as the power supply voltage VDD is increased. The delay time T_{DLY} when “VDD=VDD_{MAX}” is a delay time T_{DLY_MAX} (T_{DLY_MAX}>0).

When “VDD>VDD_{MIN}”, for example, the delay time T_{DLY} corresponding to “T_{DLY}=α×(VDD−VDD_{MIN})” may be set (a has a predetermined positive value). When “VDD>VDD_{MIN}”, the delay time T_{DLY} may be increased non-linearly as the power supply voltage VDD is increased.

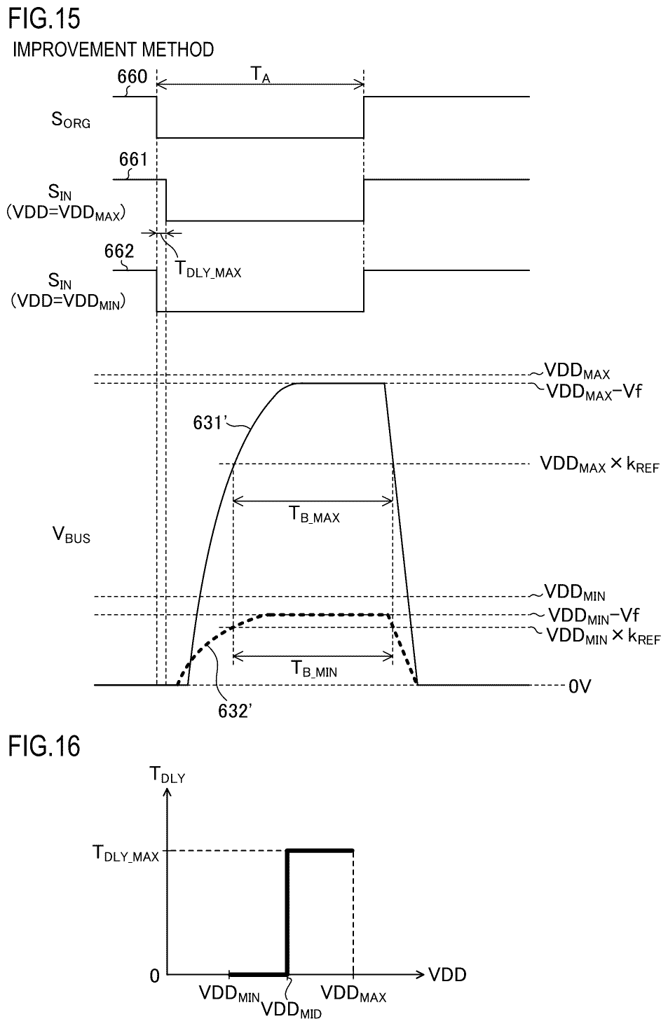

FIG. 15 shows waveforms of the original input signal S_{ORG}, the control input signal S_{IN} and the output voltage V_{BUS} in the improvement method. All the waveforms 660 to 662, 631′ and 632′ in FIG. 15 are waveforms in the improvement method, and among them, the waveform 660 is a waveform of the original input signal S_{ORG}. The waveform 661 is a waveform of the control input signal S_{IN} when “VDD=VDD_{MAX}”, and the waveform 662 is a waveform of the control input signal S_{IN} when “VDD=VDD_{MIN}”. The solid line waveform 631′ is a waveform of the output voltage V_{BUS} when “VDD=VDD_{MAX}”. The dashed line waveform 632′ is a waveform of the output voltage V_{BUS} when “VDD=VDD_{MIN}”. In FIG. 15, the waveforms 631′ and 632′ partially overlap each other.

In a state where the low level range of the original input signal S_{ORG} is a predetermined range, when “VDD=VDD_{MIN}”, the adjustment circuit 131 in the improvement method sets the low level range of the control input signal S_{IN} larger than that when “VDD=VDD_{MAX}” by the delay time T_{DLY_MAX}. Hence, in the improvement method, a difference between the high level range (T_{B_MIN}) of the output voltage V_{BUS} when “VDD=VDD_{MIN}” and the high level range (T_{B_MAX}) of the output voltage V_{BUS} when “VDD=VDD_{MAX}” is smaller than that in the reference method, and is ideally zero. This means that the H duty of the output voltage V_{BUS} is not affected by the power supply voltage VDD or is unlikely to be affected by the power supply voltage VDD.

In the reference method corresponding to FIG. 12, the output slew rate when “VDD=VDD_{MIN}” is sufficiently increased, and thus the difference described above (difference between the time T_{B_MIN} and the time T_{B_MAX}) can be set to zero. However, an increase in the output slew rate causes an increase in radiation noise. In the improvement method, the difference described above can be decreased (can be ideally set to zero) without the increase in radiation noise being caused.

Although in the example of FIG. 14, the delay time T_{DLY} is continuously changed according to the power supply voltage VDD, the delay time T_{DLY} may be stepwise changed according to the power supply voltage VDD. For example, a configuration may be adopted in which as shown in FIG. 16, when “VDD_{MIN}≤VDD<VDD_{MID}” holds true, the delay time T_{DLY} is not inserted (that is, “T_{DLY}=0”), and when “VDD_{MID}≤VDD≤VDD_{MAX}” holds true, the delay time T_{DLY} is inserted (that is, for example, “T_{DLY}=T_{DLY_MAX}>0”). The voltage VDD_{MID} is higher than the minimum voltage VDD_{MIN}, and is lower than the maximum voltage VDD_{MAX}, and for example, “VDD_{MID}=(VDD_{MIN}+VDD_{MAX})/2”. Although not shown in particular, the delay time T_{DLY} may be variably set in two or more stages according to the power supply voltage VDD.

### [Supplementary Notes]

Supplementary items, applied technology, variation technology or the like for the above embodiment will be described.

The communication system 1 can be installed in a vehicle such as an automobile. In the vehicle such as an automobile, as a communication system which performs bidirectional communication conforming to the LIN standard or the CXPI standard, the communication system 1 can be used. More specifically, for example, communication between the transceiver 10 and the other side device 30 can be used as communication of signals for realizing body control of power windows, mirrors, electric seats, door locks or the like provided in an automobile.

However, the communication system 1 is not limited to being used in a vehicle. The communication system 1 can be applied to any application in which relatively low speed communication is performed.

The transceiver 10 includes a signal transmitting apparatus which generates an output signal corresponding to the original input signal S_{ORG} at the bus connection terminal BUS functioning as an output terminal (in other words, which transmits the output signal from the bus connection terminal BUS). The constituent elements of the signal transmitting apparatus include the transmission circuit TX and can further include the bus connection terminal BUS. A semiconductor device which includes the functions of the transceiver 10 and the microcomputer 20 may be formed, and in this case, the signal transmitting apparatus is provided in the semiconductor device. The control input signal supply circuit 130 (in particular, the adjustment circuit 131) functions as a signal generation circuit which generates the control input signal S_{IN} from the original input signal S_{ORG}.

For any signal or voltage, the relationship between a high level and a low level which has been described above may be reversed without departing from the spirit of the above description. Hence, for example, a variation may be adopted in which the high level in the original input signal S_{ORG} is associated with the low level in the control input signal S_{IN}, and the low level in the original input signal S_{ORG} is associated with the high level in the control input signal S_{IN}. The adjustment circuit 131 of the variation generates a down edge in the control input signal S_{IN} when an up edge occurs in the original input signal S_{ORG} and generates an up edge in the control input signal S_{IN} when a down edge occurs in the original input signal S_{ORG}.

The type of channel of the FET (field-effect transistor) described in the embodiment is an example. The type of channel of any FET can be changed between the P-channel type and the N-channel type without departing from the spirit of the above description.

As long as no disadvantage occurs, any of the transistors described above may be any type of transistor. For example, as long as no disadvantage occurs, any of the transistors which is described above as the MOSFET can be replaced with a junction FET, an IGBT (Insulated Gate Bipolar Transistor) or a bipolar transistor. Any of the transistors includes a first electrode, a second electrode and a control electrode. In the FET, one of the first and second electrodes is the drain, the other is the source and the control electrode is the gate. In the IGBT, one of the first and second electrodes is the collector, the other is the emitter and the control electrode is the gate. In the bipolar transistor which does not belong to the IGBT, one of the first and second electrodes is the collector, the other is the emitter and the control electrode is the base.

The embodiment of the present disclosure can be changed variously as necessary within the scope of the technical ideas indicated in the scope of claims. The above embodiment is merely an example of the embodiment of the present disclosure, and the meanings of the terms in the present disclosure or the constituent elements are not limited to those described in the above embodiment. Specific numerical values indicated in the above description are merely examples and can naturally be changed to various numerical values.

### <<Additional Notes>>

Additional notes are provided for the present disclosure the specific configuration examples of which are shown in the embodiment described above.

A signal transmitting apparatus (10) according to an aspect of the present disclosure includes: an output terminal (BUS) configured to be connected to an application end (50) of a power supply voltage (VDD) via a pull-up resistor (52) and a backcurrent prevention diode (53); an output transistor (111) provided between the output terminal and a ground; a capacitor (112) connected between a gate of the output transistor and the output terminal; a signal generation circuit (130) configured to generate a control input signal (S_{IN}) based on an original input signal (S_{ORG}); and a charge-discharge circuit (120) configured to charge or discharge the gate of the output transistor according to the control input signal, the output transistor is turned on or off through the charging or the discharging of the gate of the output transistor to generate an output signal (V_{BUS}) corresponding to the original input signal and the control input signal at the output terminal, the backcurrent prevention diode has a forward direction from the application end of the power supply voltage toward the output terminal, the charge-discharge circuit charges the gate of the output transistor to turn on the output transistor when the control input signal has a first level (for example, a high level), discharges the gate of the output transistor to turn off the output transistor when the control input signal has a second level (for example, a low level) and sets values of a charge current (I_{C}) and a discharge current (I_{D}) for the gate of the output transistor according to the power supply voltage and the signal generation circuit adjusts, according to the power supply voltage, a range in which the control input signal has the second level (first configuration).

There is a concern that the presence of the backcurrent prevention diode may cause a variation in the high level range of the output signal depending on the power supply voltage even if the original input signal is constant. In the configuration described above, the range in which the control input signal has the second level is adjusted according to the power supply voltage, and thus it is possible to suppress the variation. In other words, it is possible to reduce the dependance of the output signal on the power supply voltage.

Preferably, in the signal transmitting apparatus according to the first configuration described above, the signal generation circuit causes a level of the control input signal to transition from the first level to the second level in response to a transition of a level of the original input signal from a third level (for example, a high level) to a fourth level (for example, a low level), and causes the level of the control input signal to transition from the second level to the first level in response to a transition of the level of the original input signal from the fourth level to the third level, and in a state where a range in which the original input signal has the fourth level is a predetermined range, when the power supply voltage has a predetermined first voltage value (for example, a voltage VDD_{MIN}), the signal generation circuit sets the range in which the control input signal has the second level larger than when the power supply voltage has a predetermined second voltage value (for example, a VDD_{MAX}) higher than the first voltage value (second configuration).

In this way, it is possible to suppress a variation in the high level range of the output signal which depends on the power supply voltage.

Preferably, in the signal transmitting apparatus according to the first configuration described above, the signal generation circuit causes a level of the control input signal to transition from the first level to the second level in response to a transition of a level of the original input signal from a third level (for example, a high level) to a fourth level (for example, a low level), and causes the level of the control input signal to transition from the second level to the first level in response to a transition of the level of the original input signal from the fourth level to the third level, and the signal generation circuit is configured to set the level of the control input signal to the first level (for example, a high level) when the original input signal has the third level (for example, a high level) and to be able to insert a delay time (T_{DLY}) corresponding to the power supply voltage when the level of the original input signal transitions from the third level to the fourth level to cause the level of the control input signal to transition from the first level to the second level, that is, during a period after the former transition until the latter transition (third configuration).

In this way, it is possible to suppress a variation in the high level range of the output signal which depends on the power supply voltage.

Preferably, in the signal transmitting apparatus according to the third configuration described above, the signal generation circuit causes the level of the control input signal to transition from the first level (for example, a high level) to the second level without providing the delay time when the power supply voltage has a predetermined first voltage value (for example, a VDD_{MIN}), and the level of the original input signal transitions from the third level (for example, a high level) to the fourth level, and causes the level of the control input signal to transition from the first level to the second level after the delay time when the power supply voltage has a predetermined second voltage value (for example, a VDD_{MAX}) higher than the first voltage value, and the level of the original input signal transitions from the third level to the fourth level (fourth configuration).

Preferably, in the signal transmitting apparatus according to any one of the first to fourth configurations described above, the charge-discharge circuit increases the charge current and the discharge current for the gate of the output transistor as the power supply voltage is increased (fifth configuration).

In this way, the slew rate of the output signal can be increased as the power supply voltage is increased, and consequently, it is possible to suppress the dependence of the high level range or the low level range of the output signal on the power supply voltage.

Preferably, in the signal transmitting apparatus according to any one of the first to fifth configurations described above, the charge-discharge circuit includes: a charging circuit (121) configured to supply the charge current to the gate of the output transistor during a period in which the control input signal has the first level; and a discharging circuit (122) configured to draw the discharge current from the gate of the output transistor during a period in which the control input signal has the second level (sixth configuration).

Preferably, in the signal transmitting apparatus according to any one of the first to sixth configurations described above, a drain of the output transistor is connected to the output terminal via another backcurrent prevention diode (113) that has a forward direction from the output terminal toward the ground, or is directly connected to the output terminal (seventh configuration).

1. A signal transmitting apparatus comprising:
an output terminal configured to be connected to an application end of a power supply voltage via a pull-up resistor and a backcurrent prevention diode;
an output transistor provided between the output terminal and a ground;
a capacitor connected between a gate of the output transistor and the output terminal;
a signal generation circuit configured to generate a control input signal based on an original input signal; and
a charge-discharge circuit configured to charge or discharge the gate of the output transistor according to the control input signal,
wherein the output transistor is turned on or off through the charging or the discharging of the gate of the output transistor to generate an output signal corresponding to the original input signal and the control input signal at the output terminal,
the backcurrent prevention diode has a forward direction from the application end of the power supply voltage toward the output terminal,
the charge-discharge circuit
charges the gate of the output transistor to turn on the output transistor when the control input signal has a first level,
discharges the gate of the output transistor to turn off the output transistor when the control input signal has a second level and
sets values of a charge current and a discharge current for the gate of the output transistor according to the power supply voltage and
the signal generation circuit adjusts, according to the power supply voltage, a range in which the control input signal has the second level.

2. The signal transmitting apparatus according to claim 1,
wherein the signal generation circuit
causes a level of the control input signal to transition from the first level to the second level in response to a transition of a level of the original input signal from a third level to a fourth level, and
causes the level of the control input signal to transition from the second level to the first level in response to a transition of the level of the original input signal from the fourth level to the third level, and
in a state where a range in which the original input signal has the fourth level is a predetermined range, when the power supply voltage has a predetermined first voltage value, the signal generation circuit sets the range in which the control input signal has the second level larger than when the power supply voltage has a predetermined second voltage value higher than the first voltage value.

3. The signal transmitting apparatus according to claim 1,
wherein the signal generation circuit
causes a level of the control input signal to transition from the first level to the second level in response to a transition of a level of the original input signal from a third level to a fourth level, and
causes the level of the control input signal to transition from the second level to the first level in response to a transition of the level of the original input signal from the fourth level to the third level, and
the signal generation circuit is configured
to set the level of the control input signal to the first level when the original input signal has the third level and
to be able to insert a delay time corresponding to the power supply voltage when the level of the original input signal transitions from the third level to the fourth level to cause the level of the control input signal to transition from the first level to the second level, that is, during a period after the former transition until the latter transition.

4. The signal transmitting apparatus according to claim 3,
wherein the signal generation circuit
causes the level of the control input signal to transition from the first level to the second level without providing the delay time when the power supply voltage has a predetermined first voltage value, and the level of the original input signal transitions from the third level to the fourth level, and
causes the level of the control input signal to transition from the first level to the second level after the delay time when the power supply voltage has a predetermined second voltage value higher than the first voltage value, and the level of the original input signal transitions from the third level to the fourth level.

5. The signal transmitting apparatus according to claim 1,
wherein the charge-discharge circuit increases the charge current and the discharge current for the gate of the output transistor as the power supply voltage is increased.

6. The signal transmitting apparatus according to claim 1,
wherein the charge-discharge circuit includes:
a charging circuit configured to supply the charge current to the gate of the output transistor during a period in which the control input signal has the first level; and
a discharging circuit configured to draw the discharge current from the gate of the output transistor during a period in which the control input signal has the second level.

7. The signal transmitting apparatus according to claim 1,
wherein a drain of the output transistor is connected to the output terminal via another backcurrent prevention diode that has a forward direction from the output terminal toward the ground or is directly connected to the output terminal.
